(19) United States
(12) Patent Application Publication
(10) Pub. No.: US 2015/0193065 A1
(43) Pub. Date: Jul. 9, 2015

(54) TOUCH PANEL MODULE AND TOUCH DISPLAY DEVICE HAVING THE SAME

(71) Applicant: E Ink Holdings Inc., Hsinchu (TW)

(72) Inventor: Yun-Nan HSIEH, HSINCHU (TW)

(21) Appl. No.: 14/489,493

(22) Filed: Sep. 18, 2014

(30) Foreign Application Priority Data
Jan. 8, 2014 (TW) 103100691

(51) Int. Cl. G06F 3/041; H03K 17/96; G06F 3/044; G06F 3/047; G06F 3/045

(52) U.S. Cl. CPC G06F 3/0412; G06F 3/047; G06F 3/045; G06F 3/044; H03K 17/962; G06F 2203/04101; G06F 2203/04103; G06F 2203/04112

(57) ABSTRACT

A touch panel module includes a support body, first touch electrodes, plural second touch electrodes, first conductive wires, second conductive wires, and conductive through holes. The support body has a first surface and a second surface opposite to the first surface. The first touch electrodes are located on the first surface. The second touch electrodes are located on the second surface, and the orthogonal projections of which on the first surface intersect the first touch electrodes. The first conductive wires are located on the first surface and respectively electrically connected to the first touch electrodes. The second conductive wires are located on the first surface, and the second conductive wires and the second touch electrodes are disposed in an intersection arrangement. The conductive through holes are located in the support body and respectively electrically interconnect the second touch electrodes and the second conductive wires.

### RELATED APPLICATIONS

This application claims priority to Taiwanese Application Serial Number 103100691, filed Jan. 8, 2014, which is herein incorporated by reference.

### BACKGROUND

1. Field of Invention

The present invention relates to a touch panel module and a touch display device.

2. Description of Related Art

Among the different types of consumer electronic products available in the market today, portable electronic devices that utilize a touch panel as the main communication element between users and the electronic devices have become commonplace. Examples of such consumer electronic products include personal digital assistants (PDAs), smartphones, GPS devices, and tablet computers. When using an electronic device with a touch panel, a user can input instructions directly through the touch panel instead of using keys, making the electronic device more user-friendly.

A conventional touch panel includes a support body, touch electrodes arranged in an x direction, and touch electrodes arranged in a y direction. The touch electrodes along the x direction and the touch electrodes along the y direction may be respectively located on the top surface and the bottom surface of the support body. Conductive wires must be used to electrically connect the touch electrodes along the x and y directions to a flexible printed circuit board. When the touch panel is manufactured, the conductive wires connected to the touch electrodes along the x direction are located on the top surface of the support body and also extend along the x direction. The conductive wires connected to the touch electrodes along the y direction are located on the bottom surface of the support body. The conductive wires connected to the touch electrodes along the y direction extend a distance along the y direction, and then are bent along the x direction. Thereafter, the conductive wires connected to the touch electrodes along the x direction can be bonded on the top surface of the flexible printed circuit board, and the conductive wires connected to the touch electrodes along the y direction can be bonded on the bottom surface of the flexible printed circuit board.

In recent years, consumers are requiring increasingly higher standards with respect to the outer appearance of electronic products, one result of which has been the ever-decreasing frame width at the edges of display screens. Since the conventional conductive wires connected to the touch electrodes along the y direction must be bent in the x direction from the y direction, the conductive wires connected to the touch electrodes along the y direction occupy a significant amount of space at the edge of the support body, such that it is difficult to reduce the width of the part of the frame used for covering the conductive wires. Moreover, when bonding the flexible printed circuit board, the conductive wires connected to the touch electrodes along the x direction must be bonded to the top surface of the flexible printed circuit board, and the conductive wires connected to the touch electrodes along the y direction must be bonded to the bottom surface of the flexible printed circuit board. Hence, two bonding processes are required to electrically connect the conductive wires and the flexible printed circuit board, resulting in an increase in manufacturing costs for the touch panel.

### SUMMARY

An aspect of the present invention is to provide a touch panel module.

According to an embodiment of the present invention, a touch panel module includes a support body, a plurality of first touch electrodes, a plurality of second touch electrodes, a plurality of first conductive wires, a plurality of second conductive wires, and a plurality of conductive through holes. The support body has a first surface and a second surface opposite to the first surface. The first touch electrodes are located on the first surface. The second touch electrodes are located on the second surface, and the orthogonal projections of the second touch electrodes on the first surface intersect the first touch electrodes. The first conductive wires are located on the first surface and respectively electrically connected to the first touch electrodes. The second conductive wires are located on the first surface. The second conductive wires and the second touch electrodes are disposed in an intersected arrangement. The conductive through holes are located in the support body and respectively electrically interconnect the second touch electrodes and the second conductive wires.

In one embodiment of the present invention, the touch panel module further includes a flexible printed circuit board. The flexible printed circuit board is electrically connected to the first and second conductive wires. The first and second conductive wires are connected to the same surface of the flexible printed circuit board.

In one embodiment of the present invention, the flexible printed circuit board has a touch control chip electrically connected to the first and second conductive wires.

In one embodiment of the present invention, the first conductive wires are parallel to the second conductive wires.

In one embodiment of the present invention, the second conductive wires are located at a side of the first touch electrodes.

In one embodiment of the present invention, the touch panel module further includes a grounding conductive wire. The grounding conductive wire is located on the first surface and between one of the first conductive wires and one of the second conductive wires that are adjacent to each other.

In one embodiment of the present invention, the second conductive wires are transparent conductive wires, and each of the second conductive wires is located between two adjacent first touch electrodes.

In one embodiment of the present invention, the second conductive wires are made of a material including indium tin oxide.

In one embodiment of the present invention, a width of each of the first touch electrodes is greater than a width of the first conductive wires.

In one embodiment of the present invention, a conductive glue is disposed in each of the conductive through holes.

Another aspect of the present invention is to provide a touch display device.

According to an embodiment of the present invention, a touch display device includes a display back plate and a touch panel module. The display back plate includes a driving array substrate and a front panel laminate. The front panel laminate is located on the driving array substrate and includes a transparent substrate and a display medium layer. The display medium layer is disposed between the driving array substrate and the transparent substrate. The touch panel module is located on the display back plate and electrically connected to the display back plate. The touch panel module includes a support body, a plurality of first touch electrodes, a plurality of second touch electrodes, a plurality of first conductive wires, a plurality of second conductive wires, and a plurality of conductive through holes. The support body has a first surface and a second surface opposite to the first surface. The first touch electrodes are located on the first surface. The second touch electrodes are located on the second surface, and the orthogonal projections of the second touch electrodes on the first surface intersect the first touch electrodes. The first conductive wires are located on the first surface and respectively electrically connected to the first touch electrodes. The second conductive wires are located on the first surface. The second conductive wires and the second touch electrodes are disposed in an intersected arrangement. The conductive through holes are located in the support body and respectively electrically interconnect the second touch electrodes and the second conductive wires.

In one embodiment of the present invention, the touch panel module further includes a flexible printed circuit board. The flexible printed circuit board is electrically connected to the first and second conductive wires. The first and second conductive wires are connected to the same surface of the flexible printed circuit board.

In one embodiment of the present invention, the flexible printed circuit board has a touch control chip electrically connected to the first and second conductive wires.

In one embodiment of the present invention, the first conductive wires are parallel to the second conductive wires.

In one embodiment of the present invention, the second conductive wires are located at a side of the first touch electrodes.

In one embodiment of the present invention, the touch panel module further includes a grounding conductive wire. The grounding conductive wire is located on the first surface and between one of the first conductive wires and one of the second conductive wires that are adjacent to each other.

In one embodiment of the present invention, the second conductive wires are transparent conductive wires, and each of the second conductive wires is located between two adjacent first touch electrodes.

In one embodiment of the present invention, the second conductive wires are made of a material including indium tin oxide.

In one embodiment of the present invention, a width of each of the first touch electrodes is greater than a width of the first conductive wires.

In one embodiment of the present invention, a conductive glue is disposed in each of the conductive through holes.

In the aforementioned embodiments of the present invention, the second touch electrodes are located on the second surface of the support body, and the second conductive wires are located on the first surface of the support body. Since the conductive through holes electrically interconnect the second touch electrodes and the second conductive wires, a signal can be transmitted between the second touch electrodes and the flexible printed circuit board by the second conductive wires. The second conductive wires and the first touch electrodes may be arranged on the first surface of the support body, such that the first and second conductive wires may extend in the same direction. As a result, the second conductive wires do not need to be bent to connect to the second touch electrodes. Not only can the non-display area of the support body be increased, but the frame width of the support body used to cover the second conductive wires may be reduced.

Moreover, when the flexible printed circuit board is bonded, the first and second conductive wires are located on the first surface, so that it is necessary to bond the surface of the flexible printed circuit board only one time on the first and second conductive wires. Therefore, the time for manufacturing the touch panel module may be reduced.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiments, with reference made to the accompanying drawings as follows:

FIG. 1 is a top view of a touch panel module according to an embodiment of the present invention;

FIG. 2 is a cross-sectional view of the touch panel module taken along line 2-2 shown in FIG. 1;

FIG. 3 is a cross-sectional view of the touch panel module taken along line 3-3 shown in FIG. 1;

FIG. 4 is a top view of a touch panel module according to another embodiment of the present invention;

FIG. 5 is a cross-sectional view of the touch panel module taken along line 5-5 shown in FIG. 4;

FIG. 6 is a top view of a touch panel module according to another embodiment of the present invention;

FIG. 7 is a cross-sectional view of the touch panel module taken along line 7-7 shown in FIG. 6;

FIG. 8 is a top view of a touch panel module according to another embodiment of the present invention;

FIG. 9 is a perspective view of a touch display device according to an embodiment of the present invention; and

FIG. 10 is a cross-sectional view of the touch display device taken along line 10-10 shown in FIG. 9.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

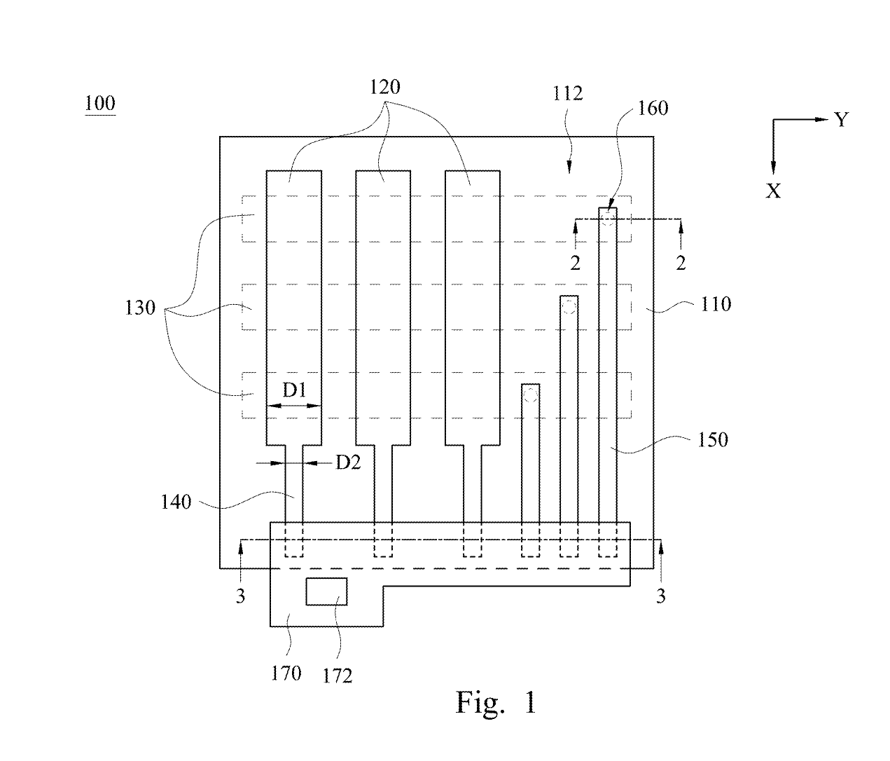

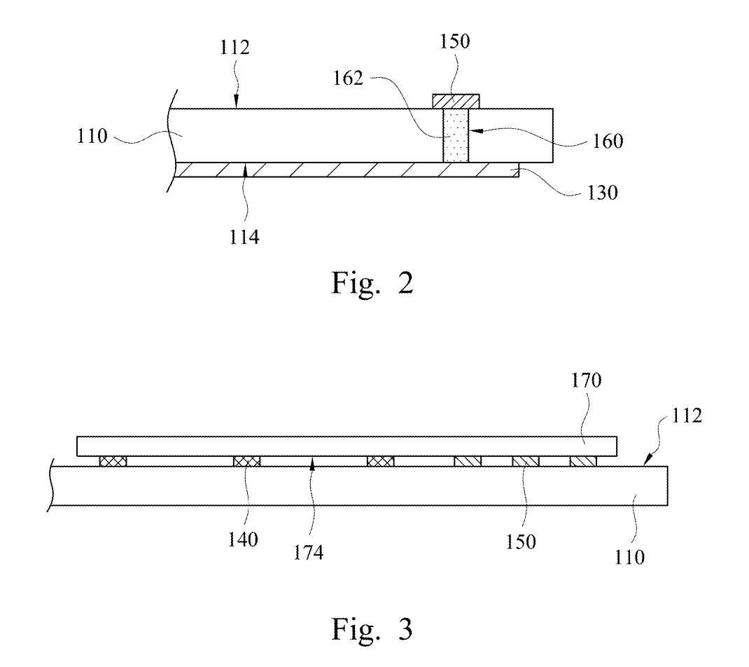

FIG. 1 is a top view of a touch panel module 100 according to an embodiment of the present invention. FIG. 2 is a cross-sectional view of the touch panel module 100 taken along line 2-2 shown in FIG. 1. As shown in FIG. 1 and FIG. 2, the touch panel module 100 includes a support body 110, a plurality of first touch electrodes 120, a plurality of second touch electrodes 130, a plurality of first conductive wires 140, a plurality of second conductive wires 150, and a plurality of conductive through holes 160. The support body 110 has a first surface 112 and a second surface 114 opposite to the first surface 112. The first touch electrodes 120 are located on the first surface 112 of the support body 110, and the second touch electrodes 130 are located on the second surface 114 of the support body 110. The orthogonal projections of the second touch electrodes 130 on the first surface 112 intersect the first touch electrodes 120.

The first conductive wires 140 are located on the first surface 112 of the support body 110 and are electrically connected to the first touch electrodes 120. The second conductive wires 150 are located on the first surface 112 of the support body 110, and the second conductive wires 150 and the second touch electrodes 130 located on the second surface 114 of the support body 110 are disposed in an intersected arrangement. The conductive through holes 160 are located in the support body 110 and are used to electrically interconnect the second touch electrodes 130 and the second conductive wires 150, as will be described below. Moreover, the first touch electrodes 120, and the first and second conductive wires 140, 150 are disposed in an arrangement along a direction x, while the second touch electrodes 130 are disposed in an arrangement along a direction y. That is to say, the first touch electrodes 120 are perpendicular to the second touch electrodes 130, and the first conductive wires 140 are parallel to the second conductive wires 150.

In this embodiment, the width D1 of the first touch electrodes 120 is greater than the width D2 of the first conductive wires 140. The first and second touch electrodes 120, 130 may be transparent electrodes that are made of indium tin oxide (ITO), but the present invention is not limited in this regard. The first and second conductive wires 140, 150 may be metal lines that are made of copper, but the present invention is not limited in this regard. A conductive glue 162 is disposed in each of the conductive through holes 160, such that the second touch electrodes 130 are electrically connected to the second conductive wires 150. The support body 110 may be made of a material including polyethylene terephthalate (PET), polymethyl methacrylate (PMMA), or glass, but the present invention is not limited in this regard.

FIG. 3 is a cross-sectional view of the touch panel module 100 taken along line 3-3 shown in FIG. 1. As shown in FIG. 1 and FIG. 3, the touch panel module 100 further includes a flexible printed circuit board 170 (FPC). The flexible printed circuit board 170 has a touch control chip 172. The first and second conductive wires 140, 150 are connected to the same surface 174 (e.g., a bottom surface) of the flexible printed circuit board 170, and the touch control chip 172 of the flexible printed circuit board 170 is electrically connected to the first and second conductive wires 140, 150. In this embodiment, the second conductive wires 150 can transmit signals to the touch control chip 172 of the flexible printed circuit board 170, and the first conductive wires 140 can receive signals from the touch control chip 172 of the flexible printed circuit board 170.

When an intersection position of the first and second touch electrodes 120, 130 is pressed, the electric field between the first and second touch electrodes 120, 130 is changed to form an induction capacitor. The pressed position of the first and second touch electrodes 120, 130 may be obtained by the touch control chip 172 and transmitted to a system terminal, such that the system terminal executes actions corresponding to pressing, page turning, zoom-in, or zoom-out, and subsequently returns signals to the touch panel module 100 to realize display. In order to prevent signal disturbance between the first and second conductive wires 140, 150, the distance between the two first and second conductive wires 140, 150 that are adjacent to each other cannot be too close, and such a distance may vary depending on the design of the touch control chip 172.

The second touch electrodes 130 are located on the second surface 114 of the support body 110. The second conductive wires 150 are located on the first surface 112 of the support body 110, and are located at a side of the first touch electrodes 120. Since the conductive through holes 160 in the support body 110 electrically interconnect the second touch electrodes 130 and the second conductive wires 150 through use of the conductive glue 162 as described above, a signal can be transmitted between the second touch electrodes 130 and the flexible printed circuit board 170 by the second conductive wires 150. The second conductive wires 150 and the first touch electrodes 120 may be arranged on the first surface 112 of the support body 110 (i.e., the first and second conductive wires 140, 150 are arranged on the first surface 112 of the support body 110), such that the first and second conductive wires 140, 150 may extend in the same direction x and connect to the flexible printed circuit board 170. As a result, the second conductive wires 150 do not need to be bent on the second surface 114 of the support body 110 to connect to the second touch electrodes 130, as in the case of the conventional design. Not only the non-display area of the support body 110 (i.e., the area of the second conductive wires 150 at the right side of the first touch electrodes 120) can be decreased, but the front frame width of the support body 110 used to cover the second conductive wires 150 may be reduced, thereby realizing space savings and enhanced aesthetics.

Furthermore, when the flexible printed circuit board 170 is bonded to the first and second conductive wires 140, 150, the first and second conductive wires 140, 150 are located on the first surface 112 of the support body 110, so that it is necessary to bond the surface 174 of the flexible printed circuit board 170 only one time on the first and second conductive wires 140, 150 through a single bonding process. As a result, the manufacturing process of the touch panel module 100 may be simplified and the manufacturing time thereof may be reduced.

It is to be noted that the connection relationships and the materials of the elements described above will not be repeated in the following description.

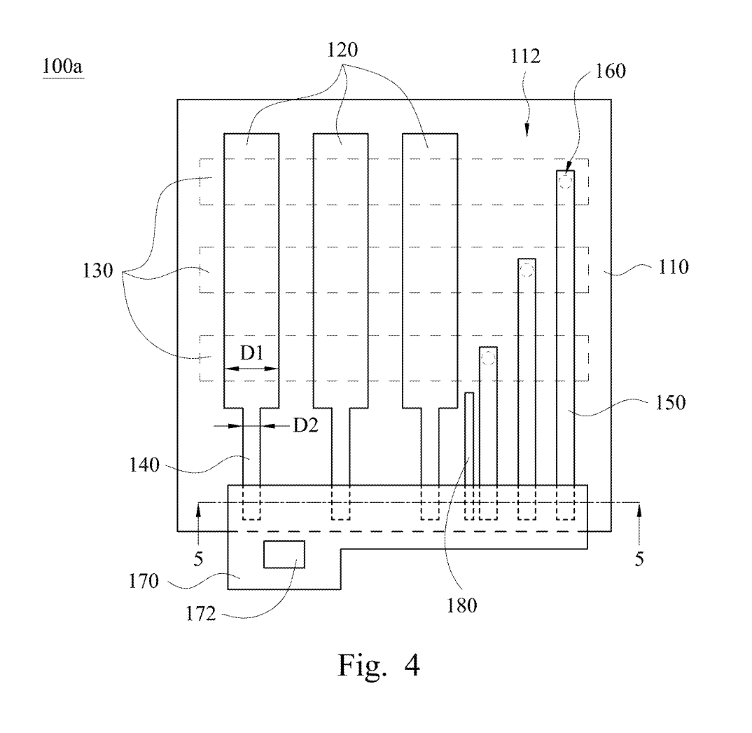

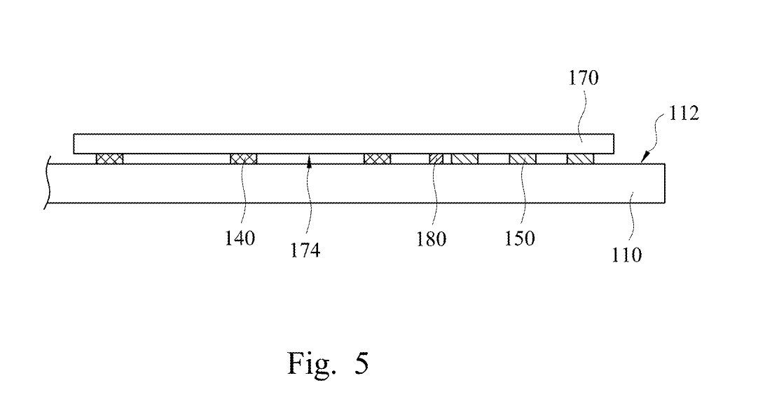

FIG. 4 is a top view of a touch panel module 100a according to another embodiment of the present invention. FIG. 5 is a cross-sectional view of the touch panel module 100a taken along line 5-5 shown in FIG. 4. As shown in FIG. 4 and FIG. 5, the touch panel module 100a includes the support body 110, the first touch electrodes 120, the second touch electrodes 130, the first conductive wires 140, the second conductive wires 150, and the conductive through holes 160. The difference between this embodiment and the embodiment shown in FIGS. 1 and 3 is that the touch panel module 100a further includes a grounding conductive wire 180. The grounding conductive wire 180 is located on the first surface 112 of the support body 110 and between one of the first conductive wires 140 and one of the second conductive wires 150 that are adjacent to each other.

The grounding conductive wire 180 can provide a reference electric potential for the touch control chip 172, such that the touch control chip 172 is able to more accurately perform determinations with respect to the signals of the first and second conductive wires 140, 150. In this embodiment, the first and second conductive wires 140, 150 and the grounding conductive wire 180 are located on the first surface 112 of the support body 110, so that the surface 174 of the flexible printed circuit board 170 may be bonded one time on the first and second conductive wires 140, 150 and the grounding conductive wire 180.

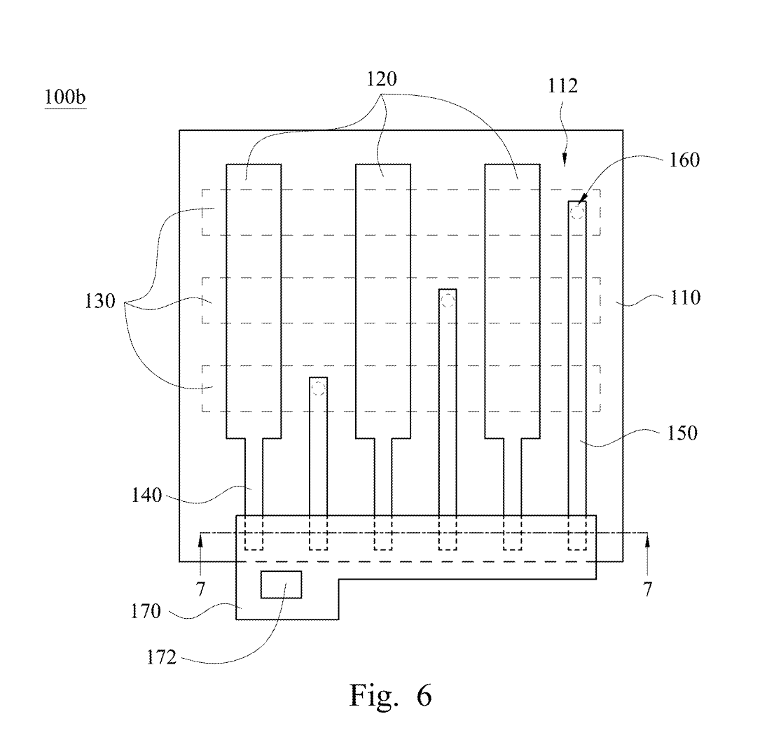

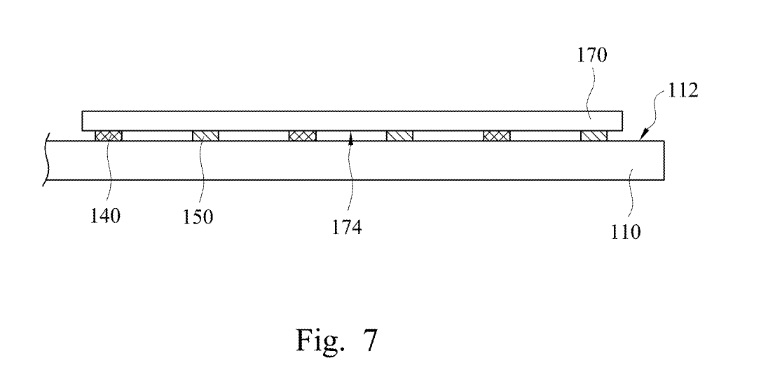

FIG. 6 is a top view of a touch panel module 100b according to another embodiment of the present invention. FIG. 7 is a cross-sectional view of the touch panel module 100b taken along line 7-7 shown in FIG. 6. As shown in FIG. 6 and FIG. 7, the touch panel module 100b includes the support body 110, the first touch electrodes 120, the second touch electrodes 130, the first conductive wires 140, the second conductive wires 150, and the conductive through holes 160. The difference between this embodiment and the embodiment shown in FIGS. 1 and 3 is that the second conductive wires 150 are transparent conductive wires. For example, the second conductive wires 150 may be made of a material including indium tin oxide. The conductive glue 162 (see FIG. 2) disposed in the conductive through holes 160 is a transparent conductive glue. As a result, each of the second conductive wires 150 may be located between two adjacent first touch electrodes 120, and the second conductive wires 150 are not clearly visible in the display area (i.e., the area of the first and second touch electrodes 120, 130) of the support body 110.

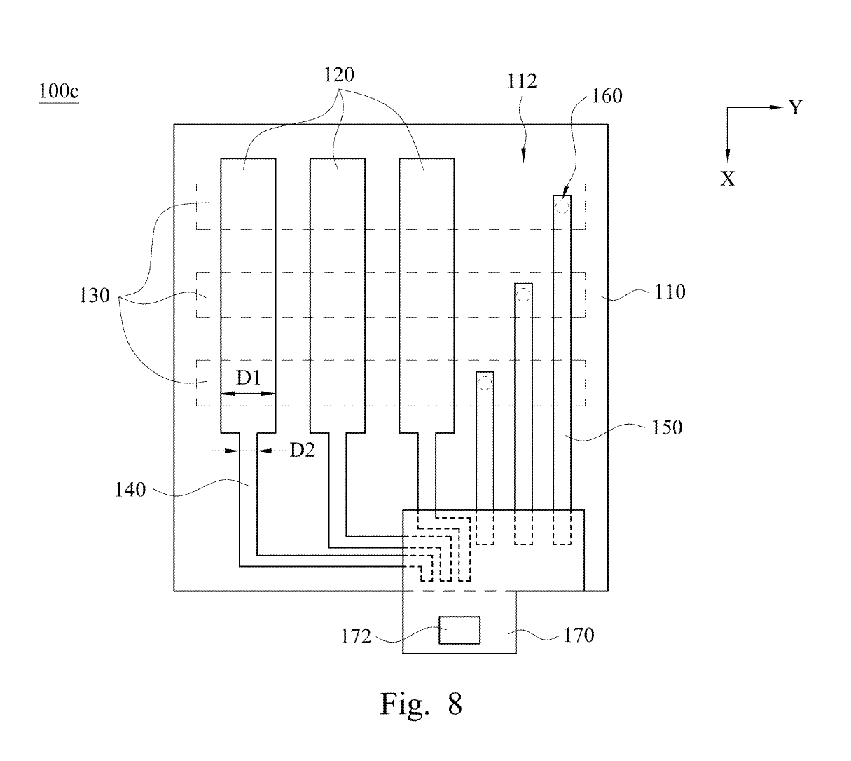

FIG. 8 is a top view of a touch panel module 100c according to another embodiment of the present invention. The touch panel module 100c includes the support body 110, the first touch electrodes 120, the second touch electrodes 130, the first conductive wires 140, the second conductive wires 150, and the conductive through holes 160. The difference between this embodiment and the embodiment shown in FIG. 1 is that the first conductive wires 140 of the touch panel module 100c are bent to electrically connect to the touch control chip 172 of the flexible printed circuit board 170, such that the ends of the flexible printed circuit board 170 connected to the flexible printed circuit board 170 are more centralized. As a result, the width of the flexible printed circuit board 170 may be reduced, such that the design of the flexible printed circuit board 170 can be more flexible, and the material cost of the flexible printed circuit board 170 can be reduced due to the smaller area thereof.

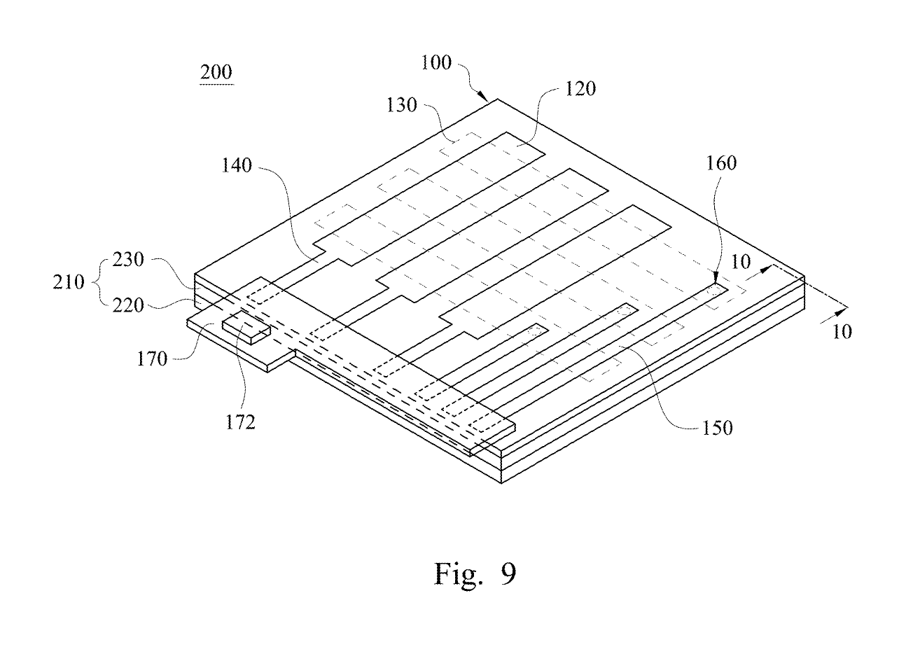

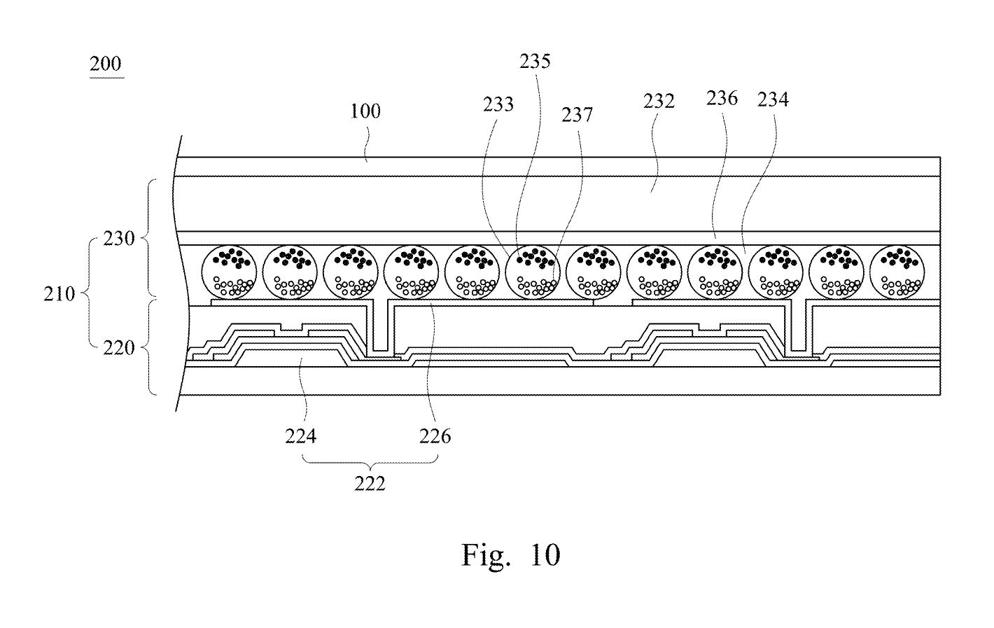

FIG. 9 is a perspective view of a touch display device 200 according to an embodiment of the present invention. FIG. 10 is a cross-sectional view of the touch display device 200 taken along line 10-10 shown in FIG. 9. As shown in FIG. 9 and FIG. 10, the touch display device 200 includes a display back plate 210 and the touch panel module 100 shown in FIG. 1. The display back plate 210 includes a driving array substrate 220 and a front panel laminate 230. The front panel laminate 230 is located on the driving array substrate 220 and includes a transparent substrate 232 and a display medium layer 234. The display medium layer 234 is disposed between the driving array substrate 220 and the transparent substrate 232. The touch panel module 100 is located on the display back plate 210 and electrically connected to the display back plate 210. The touch panel module 100 includes the support body 110, the first touch electrodes 120, the second touch electrodes 130, the first conductive wires 140, the second conductive wires 150, and the conductive through holes 160.

The driving array substrate 220 includes a plurality of pixel units 222. Each of the pixel units 222 includes a thin film transistor 224 and a pixel electrode 226. The front panel laminate 230 further includes a common electrode 236. The display medium layer 234 includes a plurality of microencapsules 233. Each of the microencapsules 233 includes a plurality of dark electrophoretic particles 235 and a plurality of bright electrophoretic particles 237. Moreover, the common electrode 236 is located on the transparent substrate 232 and faces the pixel electrodes 226. The microencapsules 233 are located between the common electrode 236 and the pixel electrodes 226.

In use, the touch panel module 100 provides the touch display device 200 with a touch function. The display back plate 210 may change electric fields formed between the common electrode 236 and each of the pixel electrodes 226, such that the bright electrophoretic particles 237 or the dark electrophoretic particles 235 are near an upper side of the microencapsules 233. When the bright electrophoretic particles 237 are near the upper side of the microencapsules 233, and the dark electrophoretic particles 235 are near the lower side of the microencapsules 233, the display back plate 210 can reflect an incident light from the environment so as to display as a bright surface in the area of the microencapsules 233 controlled in this manner. On the other hand, when the bright electrophoretic particles 237 are near the lower side of the microencapsules 233, and the dark electrophoretic particles 235 are near the upper side of the microencapsules 233, the display back plate 210 does not reflect an incident light from the environment so as to display as a dark surface in the area of the microencapsules 233 controlled in this manner.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A touch panel module comprising:
a support body having a first surface and a second surface opposite to the first surface;
a plurality of first touch electrodes located on the first surface;
a plurality of second touch electrodes located on the second surface, wherein orthogonal projections of the second touch electrodes on the first surface intersect the first touch electrodes;
a plurality of first conductive wires located on the first surface and respectively electrically connected to the first touch electrodes;
a plurality of second conductive wires located on the first surface, wherein the second conductive wires and the second touch electrodes are disposed in an intersected arrangement; and
a plurality of conductive through holes located in the support body and respectively electrically interconnecting the second touch electrodes and the second conductive wires.

2. The touch panel module of claim 1, further comprising:
a flexible printed circuit board electrically connected to the first and second conductive wires, wherein the first and second conductive wires are connected to the same surface of the flexible printed circuit board.

3. The touch panel module of claim 2, wherein the flexible printed circuit board has a touch control chip electrically connected to the first and second conductive wires.

4. The touch panel module of claim 1, wherein the first conductive wires are parallel to the second conductive wires.

5. The touch panel module of claim 1, wherein the second conductive wires are located at a side of the first touch electrodes.

6. The touch panel module of claim 5, further comprising:
a grounding conductive wire located on the first surface and between one of the first conductive wires and one of the second conductive wires that are adjacent to each other.

7. The touch panel module of claim 1, wherein the second conductive wires are transparent conductive wires, and each of the second conductive wires is located between two adjacent first touch electrodes.

8. The touch panel module of claim 7, wherein the second conductive wires are made of a material comprising indium tin oxide.

9. The touch panel module of claim 1, wherein a width of each of the first touch electrodes is greater than a width of the first conductive wires.

10. The touch panel module of claim 1, wherein a conductive glue is disposed in each of the conductive through holes.

11. A touch display device comprising:
a display back plate comprising:
a driving array substrate; and
a front panel laminate located on the driving array substrate and comprising a transparent substrate and a display medium layer, wherein the display medium layer is disposed between the driving array substrate and the transparent substrate; and
a touch panel module located on the display back plate and electrically connected to the display back plate, wherein the touch panel module comprises:
a support body having a first surface and a second surface opposite to the first surface;
a plurality of first touch electrodes located on the first surface;
a plurality of second touch electrodes located on the second surface, wherein orthogonal projections of the second touch electrodes on the first surface intersect the first touch electrodes;
a plurality of first conductive wires located on the first surface and respectively electrically connected to the first touch electrodes;
a plurality of second conductive wires located on the first surface, wherein the second conductive wires and the second touch electrodes are disposed in an intersected arrangement; and
a plurality of conductive through holes located in the support body and respectively electrically interconnecting the second touch electrodes and the second conductive wires.

12. The touch display device of claim 11, wherein the touch panel module further comprises:
a flexible printed circuit board electrically connected to the first and second conductive wires, wherein the first and second conductive wires are connected to the same surface of the flexible printed circuit board.

13. The touch display device of claim 12, wherein the flexible printed circuit board has a touch control chip electrically connected to the first and second conductive wires.

14. The touch display device of claim 11, wherein the first conductive wires are parallel to the second conductive wires.

15. The touch display device of claim 11, wherein the second conductive wires are located at a side of the first touch electrodes.

16. The touch display device of claim 15, wherein the touch panel module further comprises:
a grounding conductive wire located on the first surface and between one of the first conductive wires and one of the second conductive wires that are adjacent to each other.

17. The touch display device of claim 11, wherein the second conductive wires are transparent conductive wires, and each of the second conductive wires is located between two adjacent first touch electrodes.

18. The touch display device of claim 17, wherein the second conductive wires are made of a material comprising indium tin oxide.

19. The touch display device of claim 11, wherein a width of each of the first touch electrodes is greater than a width of the first conductive wires.

20. The touch display device of claim 11, wherein a conductive glue is disposed in each of the conductive through holes.
